(19) United States
(12) Patent Application Publication
(10) Pub. No.: US 2024/0005048 A1
(43) Pub. Date: Jan. 4, 2024

(54) BOUNDING BOX-BASED VISUALIZATION OF COMPUTER-AIDED DESIGN (CAD) MODELS VIA PIXEL COLOR ANALYSES

(71) Applicant: Siemens Industry Software Inc., Plano, TX (US)

(72) Inventors: Robert Hofford, State College, PA (US); Daniel Dressler, Bellefonte, PA (US)

(21) Appl. No.: 17/809,685

(22) Filed: Jun. 29, 2022

(51) Int. Cl. G06F 30/12; G06T 11/00; G06T 11/40

(52) U.S. Cl. CPC G06F 30/12; G06T 11/001; G06T 11/40; G06T 2210/12

(57) ABSTRACT

A client computing system may include a model visualization engine configured to visualize a view of a computer-aided design (CAD) model in an application window, including by accessing bounding box data for non-visualized CAD parts of the CAD model, assigning a color value to each of the bounding boxes of the non-visualized CAD parts, capturing a 2D image of the view of the CAD model rendered using the bounding boxes for the non-visualized CAD parts, and analyzing the 2D image to identify pixel colors present in the 2D image to determine visible CAD parts in the view of the CAD model. The model visualization engine may further visualize the view of the CAD model by retrieving visualization data for the visible CAD parts and visualizing, in the application window, the visible CAD parts in the view of the CAD model via the retrieved visualization data.

### BACKGROUND

Computer systems can be used to create, use, and manage data for products and other items. Examples of computer systems include computer-aided design (CAD) systems (which may include computer-aided engineering (CAE) systems), visualization and manufacturing systems, product data management (PDM) systems, product lifecycle management (PLM) systems, and more. These systems may include components that facilitate the design and simulated testing of product structures and product manufacture.

### BRIEF DESCRIPTION OF THE DRAWINGS

Certain examples are described in the following detailed description and in reference to the drawings.

FIG. 1 shows an example of a client computing system that supports bounding box-based visualization of CAD models via pixel color analyses.

FIG. 2 shows an example determination of visible CAD parts for a CAD model via a pixel color analysis of rendered bounding boxes.

FIG. 3 shows an example visualization of visible CAD parts determined for a CAD model as well as an example subsequent iterative determination of additional visible CAD parts of the CAD model.

FIG. 4 shows an example of logic that a system may implement to support bounding box-based visualization of CAD models via pixel color analyses.

FIG. 5 shows an example of a system that supports bounding box-based visualization of CAD models via pixel color analyses.

### DETAILED DESCRIPTION

CAD systems and applications can be implemented in various ways. For instance, CAD applications may be offered as a cloud-based service, e.g., as a Software-as-a-Service (“SaaS”) offering in which client computing systems access centrally hosted CAD applications via locally implemented thin clients. In such client-server models, user access to CAD models may be a time-consuming and resource-consuming process, especially as CAD models continue to increase in size and complexity. Receiving and loading 3D CAD models from a server via thin clients may consume significant computing and network resources. Visualization of complex models can be particularly taxing on thin clients (e.g., application browsers) that are oftentimes limited in processing and memory capabilities.

Such limitations may become increasingly apparent for complex CAD models with numerous sub-parts. CAD models may be comprised of CAD parts, which may represent discrete, granular, or atomic objects in a CAD model and complex CAD models may be formed by nested assembly structures in which a given CAD model is formed as combination of CAD parts and CAD assemblies, which are further formed by CAD parts and CAD sub-assemblies, and further so forth. In some implementations, CAD models can be represented as product structure trees, with tree branches representing sub-assemblies and leaf nodes representing CAD parts. Any suitable CAD model formats are contemplated herein, and in modern CAD contexts, CAD models comprising thousands or millions of CAD parts are increasingly common.

Visualization of CAD models is typically performed from specific viewpoints within a 3D space that CAD models are modelled within. For a given view of a CAD model (e.g., from a particular viewpoint and viewing angle in the 3D space), only some, but not all, of the CAD parts of a CAD model may be visible. Some of the CAD parts may occlude other CAD parts of the CAD model in the given view, and in such cases the occluded CAD parts need not be displayed to properly visualize the given view of the CAD model. Determination of occluded CAD parts in CAD model views is not a trivial matter, particularly for resource-limited thin clients in SaaS-based implementations of CAD systems and CAD architectures. Conventional occlusion culling and determination of visible CAD parts and occluded CAD parts rely on algorithmically complex geometrical and spatial analyses of the 3D geometry of CAD parts of the CAD model. For CAD models with thousands or even millions of CAD parts, such complex geometrical and spatial processing of 3D geometries can be time-consuming and resource intensive, greatly limiting the feasibility, usability, and performance of thin clients in cloud-based CAD systems.

The disclosure herein may provide systems, methods, devices, and logic for bounding box-based visualization of CAD models via pixel color analyses. As described in greater detail below, the bounding box-based visualization technology of the present disclosure may support occlusion culling based on bounding boxes instead of full-detail geometry data of CAD parts. In doing so, the bounding box-based visualization features of the present disclosure may assign a unique pixel color to each bounding box of CAD parts of a CAD model and render the bounding boxes instead of the full-detail 3D geometry for a given view of the CAD model, with each CAD part bounding box colored with a unique color value. Then, analysis of a 2D image of the rendered bounding boxes can indicate which pixel color values are included in the 2D image, thus providing an indication of which bounding boxes (and corresponding CAD parts) are visible in the view of the CAD model based on the rendered bounding boxes.

As also described herein in greater detail, iterative determinations of visible CAD parts are supported. Through an iterative model visualization process, renderings of 3D geometry of visible parts and bounding boxes of non-visualized CAD parts can be performed to further determine additional visible CAD parts in subsequent iterations. Thus, the bounding box-based visualization technology of the present disclosure may support determination of visible CAD parts in a view of a CAD model through pixel color analyses of rendered bounding boxes (which may be in combination with rendered 3D geometry of previously determined visible CAD parts).

The bounding box-based visualization technology described herein may provide various technical improvements as compared to conventional CAD model visualization and occlusion culling techniques. Obtaining bounding box data from a cloud server and rendering 3D rectangular shapes may be performed at increased speed and efficiency as compared to the cumbersome loading and rendering full 3D geometry data of all of the CAD parts of a CAD model as in conventional techniques. Pixel color analyses of 2D images may also be performed with significantly lesser resource requirements and reduced computational latency than the complex geometrical spatial analyses of conventional 3D model visualization processes. As such, the bounding box-based visualization technology of the present disclosure may support determination of visible and occluded CAD parts in a view of a CAD model with increased speed, efficiency, and effectiveness, which may be particularly suitable for SaaS-based CAD application implementations. Additionally, the features described herein can support selective loading of visualization data specifically for visible CAD parts determined through bounding boxes renderings and pixel color analyses, reducing network latency and increasing the speed at which views of CAD models are visualized.

These and other bounding box-based visualization features and benefits are described in greater detail herein.

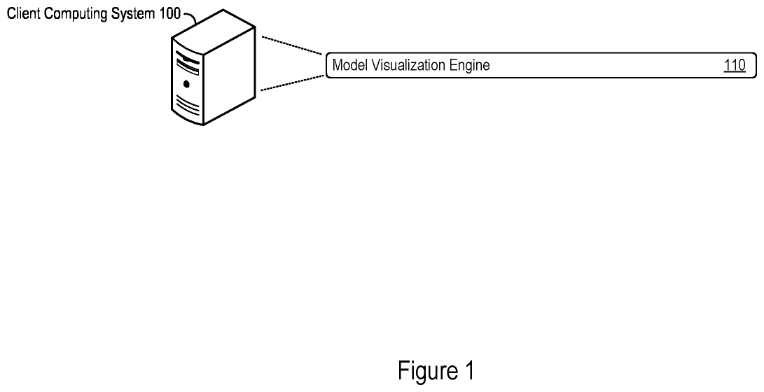

FIG. 1 shows an example of a client computing system 100 that supports bounding box-based visualization of CAD models via pixel color analyses. The client computing system 100 may take the form of a single or multiple computing devices such as application servers, compute nodes, desktop or laptop computers, smart phones or other mobile devices, tablet devices, embedded controllers, and more. In some examples, the client computing system 100 implements or executes a thin client of a CAD application, providing access to cloud-based implementations of CAD applications. The client computing system 100 may interact with a server computing system at which CAD model data is centrally stored, acting as a client in a client-server architecture to access to CAD applications, CAD models, and various CAD functionalities.

As an example implementation to support any combination of the bounding box-based visualization features described herein, the client computing system 100 shown in FIG. 1 includes a model visualization engine 110. The client computing system 100 may implement the model visualization engine 110 (including components thereof) in various ways, for example as hardware and programming. The programming for the model visualization engine 110 may take the form of processor-executable instructions stored on a non-transitory machine-readable storage medium and the hardware for the model visualization engine 110 may include a processor to execute those instructions. A processor may take the form of single processor or multi-processor systems, and in some examples, the client computing system 100 implements multiple engines using the same computing system features or hardware components (e.g., a common processor or a common storage medium).

In operation, the model visualization engine 110 may visualize a view of a CAD model in an application window, including by accessing bounding box data for non-visualized CAD parts of the CAD model. Non-visualized CAD parts may include CAD parts of the CAD model for which visualization data has not been retrieved by the client computing system 100 and bounding box data for the non-visualized CAD parts may represent a respective bounding box for the non-visualized CAD parts of the CAD model. The model visualization engine 110 may further visualize the view of the CAD model by assigning a color value to each of the bounding boxes of the non-visualized CAD parts, capturing a 2D image of the view of the CAD model rendered using the bounding boxes for the non-visualized CAD parts instead of rendered using visualization data (e.g., 3D geometry) of the non-visualized CAD parts, and analyzing the 2D image to identify pixel colors present in the 2D image to determine visible CAD parts in the view of the CAD model, wherein the visible CAD parts correspond to bounding boxes of non-visualized CAD parts determined as visible based on the identified pixel colors. Then, the model visualization engine 110 may retrieve visualization data for the visible CAD part and visualize, in the application window, the visible CAD parts in the view of the CAD model via the retrieved visualization data.

These and other bounding box-based visualization features according to the present disclosure are described in greater detail next.

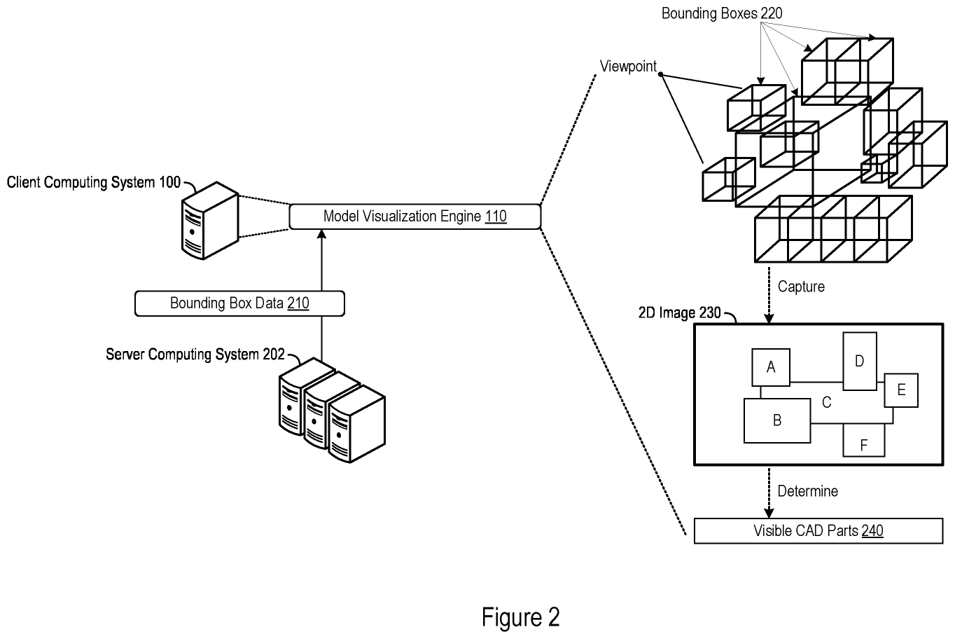

FIG. 2 shows an example determination of visible CAD parts for a CAD model via a pixel color analysis of rendered bounding boxes. The example of FIG. 2 includes a client computing system 100 and a server computing system 202. The client computing system 100 and server computing system 202 may together support a client-server (e.g., SaaS) based implementation of a CAD application, in which CAD software and model data can be centrally hosted on a CAD application server (such as the server computing system 202) and accessed via thin clients implemented by client devices (e.g., the client computing system 100). To support such features, the client computing system 100 and server computing system 202 may be communicatively linked, e.g., via the Internet, local or wide area networks, etc.

The client computing system 100 as shown in FIG. 2 includes the model visualization engine 110. The model visualization engine 110 may include any capability to support visualization of CAD models by the client computing system 100, and the model visualization engine 110 may implement any combination of the bounding box-based visualization technology of the present disclosure. For instance, the model visualization engine 110 may be a component of a thin client (e.g., a web browser) implemented by the client computing system 100 to provide local CAD application capabilities for the client computing system 100.

To visualize a given view of a CAD model, the model visualization engine 110 may determine which of the CAD parts of the CAD model are visible in the given view. In doing so, the model visualization engine 110 may differentiate or otherwise categorize CAD parts of the CAD model as visible CAD parts, non-visualized CAD parts, or any other suitable characterization. Visible CAD parts may refer to CAD parts for which the model visualization engine 110 has determined as visible in a given view of a CAD model (or previously visualized views), responsive to which the model visualization engine 110 may load visualization data to store locally on the client computing system 100. Non-visualized CAD parts may refer to CAD part of a CAD model that the model visualization engine 110 has not retrieved visualization data for, and as such may refer to any CAD parts of a CAD model not previously determined to be a visible CAD part for a visualized view of the CAD model.

Determination of visible CAD parts of the CAD model may be performed through image analyses of rendered bounding boxes. In the example of FIG. 2, the model visualization engine 110 obtains bounding box data 210 for CAD parts of a CAD model. As used herein, a bounding box may refer to any shape representation that encloses a CAD part, and need not be rectangular in shape. As such, a bounding box may take the form of a icosahedron, a sphere, or any suitable shape representation that simplifies a representation of a CAD part. Any suitable type of bounding box is thus contemplated herein to enclose a CAD part such that no portion of the CAD part extends beyond a boundary of the bounding box. The bounding box data 210 may take the form of any data that represents a bounding shape for the CAD parts, for example as coordinate pairs that represent opposite vertices of each respective bounding box, as a simple cube representation and a corresponding transformation matrix for a CAD part bounding box, a spherical center location and radius value, or in any other suitable representation format for a bounding box of a CAD part.

The model visualization engine 110 may obtain bounding box data 210 specifically for non-visualized CAD parts of the CAD model, as doing so may allow the model visualization engine 110 to represent such non-visualized CAD parts as bounding boxes instead of via full-detail 3D geometry. As described further herein, visible CAD part determinations may be performed iteratively, and thus the model visualization engine 110 need not obtain bounding box data for visible CAD parts for which visualization data has been previously retrieved, e.g., previously determined visible CAD parts for which corresponding visualization data was retrieved from the server computing system 202. Such prior retrieval may have occurred as part of a previous iteration of a model visualization process for a given view of the CAD model or as part of the visualization of a different view of the CAD model.

In some implementations, the model visualization engine 110 may initially set, flag, or characterize all CAD parts of a CAD model as non-visualized CAD parts (e.g., in an initial iteration of visible CAD part determinations for a given view). As such, the model visualization engine 110 may obtain bounding box data 210 for all CAD parts of the CAD model, even for CAD parts previously determined as visible in the visualization of a different view of a CAD model by the model visualization engine 110. In other implementations, the model visualization engine 110 may maintain characterizations of CAD parts across different view visualizations, and by doing so may deem a particular CAD part of a given view as a visible CAD part when the visualization data of the particular CAD part was previously retrieved in the visualization of a different view of the CAD model.

To support occlusion culling via bounding boxes, the model visualization engine 110 may assign a color value to each of the bounding boxes of the non-visualized CAD parts for a given view of a CAD model. Assignment of color values of may be performed in any suitable manner such that each bounding box (and corresponding CAD part) is assigned a unique color value. In some examples, the model visualization engine 110 may assign sequential RGB pixel values to respective bounding boxes (and, in effect, corresponding CAD parts). In such examples, a first bounding box may be assigned an RGB color value #00001, a next bounding box assigned an RGB color value #00002, and so forth.

The model visualization engine 110 may then render the CAD model (that is, a particular view thereof), doing so by rendering the non-visualized CAD parts of the CAD model as bounding boxes instead of the actual 3D geometry of the non-visualized CAD parts. Each given bounding box may be colored with the particular color value assigned to the bounding box, and thus each bounding box may be uniquely identified by its color value. In an initial iteration, this may include rendering all of the CAD parts of a CAD model as bounding boxes. As shown in FIG. 2, the bounding boxes 220 may represent a CAD model and each of the bounding boxes 220 may be colored uniquely in the rendering of the CAD model via bounding boxes. Note that the bounding boxes 220 in FIG. 2 are axis-aligned, but that need not be the case. Each individual bounding box can be in any orientation so long as the 3D geometry of the corresponding CAD part is enclosed in the bounding box. Note also that the model visualization engine 110 may render each of the bounding boxes 220 (and any 3D geometry of visible CAD parts) completely as the single color assigned to the bounding box. In regard, the model visualization engine 110 need not account for shading, lighting, shadows, or any other visual features of the rendered CAD model, which may increase the efficiency and speed at which the model visualization engine 110 can render the CAD model via the bounding boxes 220.

The model visualization engine 110 may render the CAD model via the bounding boxes 220 for a particular view of the CAD model that the model visualization engine 110 is to visualize in an application window of the client computing system 100. In FIG. 2, the model visualization engine 110 may render the CAD model via the bounding boxes 220 from a specific viewpoint and camera angle that defines the particular view of the CAD model. Then, the model visualization engine 110 may capture a 2D image of the view of the CAD model comprised of the bounding boxes 220, which the model visualization engine 110 may then analyze to determine visible pixel colors to correlate the visible pixel colors to assigned color values of corresponding bounding boxes in order to identify visible CAD parts for the particular view.

In the example shown in FIG. 2, the model visualization engine 110 captures the 2D image 230 of the view of the CAD model in which the non-visualized CAD parts are rendered as the bounding boxes 220 of the non-visualized CAD parts instead of rendered as a 3D geometry of the non-visualized CAD parts. For instance, the model visualization engine 110 may capture the 2D image 230 as a bitmap, and individual pixels of the bitmap may have specific pixel color values.

The model visualization engine 110 may determine visible CAD parts by analyzing the 2D image 230 of the view of the CAD model. To do so, the model visualization engine 110 may process the 2D image 230 to identify the pixel colors included in the 2D image 230 and then correlate the identified pixel colors to the assigned color values for the bounding boxes 220. Any pixel color included in the 2D image 230 that is an assigned color of a bounding box may indicate that the corresponding CAD part of the bounding box is visible in a given view of the CAD model. As such, the model visualization engine 110 may determine that this corresponding CAD part is a visible CAD part for the view of the CAD model.

In the example shown in FIG. 2, the 2D image 230 includes six (6) colored sections labeled as A-F. Each of the sections A-F may be colored by a different pixel color, and the pixel colors of sections A-F may correspond to six (6) different bounding boxes of six (6) different CAD parts of the CAD model. The model visualization engine 110 may perform a lookup for the six (6) different pixel color values included in the 2D image 230 and identify the specific bounding boxes assigned these color values, which in turn identifies the six (6) corresponding CAD parts with visible bounding boxes in the rendered view. The model visualization engine 110 may determine these six (6) corresponding CAD parts as the visible CAD parts 240 for a given view of the CAD model.

In such a manner, the model visualization engine 110 may utilize bounding box renderings and pixel color analyses of a captured 2D image in order to determine visible CAD parts in a given view of a CAD model. Analyses of a captured 2D image may be performed with increased speed and efficiency as compared to conventional spatial analyses of complex 3D geometries. Instead, by identifying specific pixel color values of a captured 2D image, the model visualization engine 110 may quickly identify bounding boxes visible in the rendered view simply through identification of each different pixel color value present in the 2D image and performing lookup operations to determine the corresponding CAD parts for each identified pixel color value.

Note that the model visualization engine 110 may determine visible CAD parts of a view of CAD model via bounding box renderings and pixel color analyses as a background process that is not displayed via a user interface of a CAD application. That is, the model visualization engine 110 may render CAD models via bounding boxes such that the rendered bounding boxes are not displayed or otherwise visible to CAD application users. In that regard, the rendering of the bounding boxes 220 as well as the capture and analysis of the 2D image 230 may be performed “off-screen” as the 2D image 230 is not visible to a user. Indeed, such an off-screen rendered view of the CAD model via bounding boxes would appear as a collection of overlapping colored boxes, and incrementally assigned color values would make bounding boxes in such an image nearly indistinguishable, providing limited visual cues to a human observer. While such distinguishing of pixel color values (and thus visible bounding boxes and CAD parts) may be near-impossible for a human eye, such an image can be quickly analyzed and processed by the model visualization engine 110 to determine visible CAD parts for a given view of a CAD model.

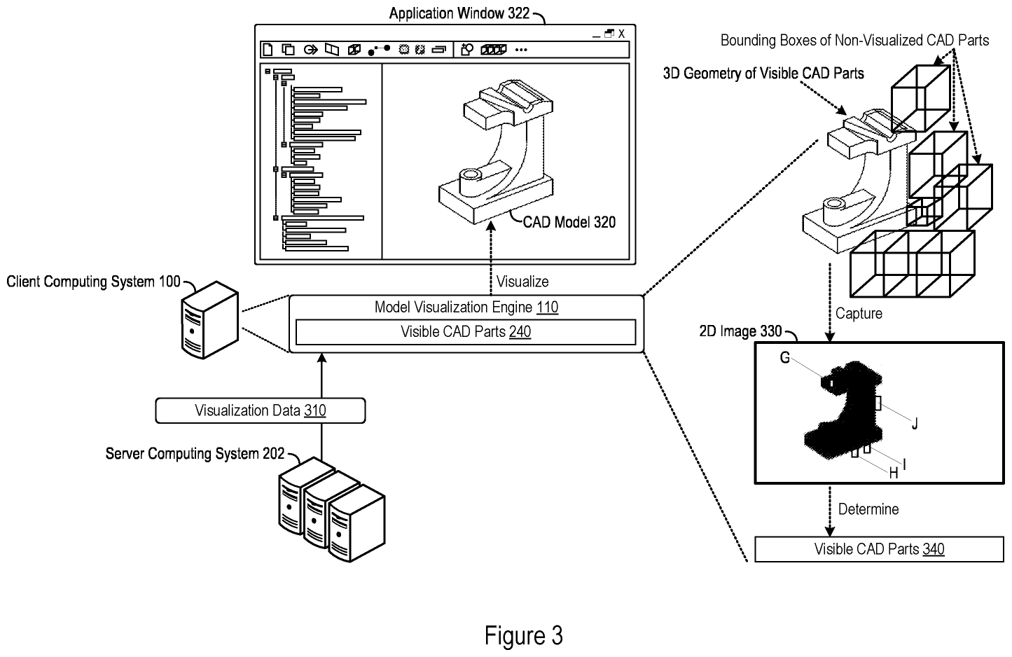

To visualize the given view of a CAD model in an application window, the model visualization engine 110 may visualize only the CAD parts of a CAD model determined as visible CAD parts for a given view of the CAD model, such as the visible CAD parts 240 of FIG. 2. Moreover, the model visualization engine 110 may perform subsequent iterations of background bounding box renderings of non-visualized CAD parts together with 3D geometry of visible CAD parts as well as pixel color analyses of 2D images in order to further identify additional visible CAD parts. Example features of visualizations of determined visible CAD parts and subsequent iterative determinations of additional visible CAD parts of a given view of a CAD model are described next with reference to FIG. 3.

FIG. 3 shows an example visualization of visible CAD parts determined for a CAD model as well as an example subsequent iterative determination of additional visible CAD parts of the CAD model. In the example of FIG. 3, the model visualization engine 110 of the client computing system 100 retrieves visualization data 310 for the visible CAD parts 240 determined for a CAD model, e.g., determined as described for FIG. 2. The visualization data 310 may comprise any data that supports the visualization of a geometry of a CAD part. As such, the visualization data 310 for the visible CAD parts 240 may comprise 3D geometry or full-detail geometry data of each CAD part of the visible CAD parts 240. Visualization data for a CAD model may be centrally hosted in a SaaS based implementation of a CAD application, and the model visualization engine 110 may retrieve visualization data for determined CAD parts from cloud servers or other computing systems remote to an application client used to visualize CAD models locally on a client computing system. In FIG. 3, the model visualization engine 110 retrieves (e.g., loads) the visualization data 310 for the visible CAD parts 240 from a server computing system 202.

Upon retrieving visualization data for visible CAD parts, the model visualization engine 110 may visualize (e.g., display) a CAD model in an application window, doing so by visualizing the visible CAD parts for a given view of the CAD model and for which visualization data of the visible CAD parts has been retrieved from a remote server. In FIG. 3, the model visualization engine 110 visualizes a given view of a CAD model 320 in an application window 322 by visualizing the visible CAD parts 240 via the visualization data 310 retrieved for the visible CAD parts 240. In doing so, the model visualization engine 110 may cause display of the 3D geometry of the determined visible CAD parts in the view of the CAD model 320, such visible CAD parts determined through off-screen rendering of bounding boxes and subsequent 2D image analysis. As such, the model visualization engine 110 may support visualization of CAD models via visible CAD part determinations from rendered bounding boxes of CAD parts of the CAD model.

A single iteration of determining visible CAD parts for a view of a CAD model via the bounding box-based visualization technology of the present disclosure may provide an elegant and efficient process to visualize the view of the CAD model. For some 3D part geometries, a particular CAD part may have a relatively large bounding box but the actual 3D geometry of the CAD part may occupy only a relatively small portion of the bounding box. In such cases, there may be other CAD parts visible behind the bounding box of the CAD part as the actual 3D geometry of the CAD part may occlude only a relatively small portion of CAD parts located behind the bounding box in a view of the CAD model. To increase the accuracy of visible part determinations for a CAD model, the model visualization engine 110 may perform multiple iterations of visible CAD part determinations to progressively identify additional visible CAD parts that are not fully occluded by rendered bounding boxes of CAD parts of the CAD model, also referred to herein as iterations of a model visualization process.

In some implementations, the model visualization engine 110 may iteratively determine visible CAD parts for a given view of a CAD model, doing so through off-screen renderings of a combination of bounding boxes for non-visualized CAD parts and 3D geometry of previously determined visible CAD parts. In each given iteration, the model visualization engine 110 may determine additional visible CAD parts through the off-screen combined 3D geometry-bounding box rendering of the given view of a CAD model, doing so in a consistent matter as described herein.

To provide an illustrative example through FIG. 3, the model visualization engine 110 may determine and display the visible CAD parts 240 in an application window 322 as part of an initial iteration of visible CAD part determinations in visualizing a given view of the CAD model 320. Through the initial iteration, the model visualization engine 110 may categorize some of the CAD parts of the CAD model 320 as visible CAD parts and other CAD parts of the CAD model 320 as non-visualized CAD parts, e.g., not determined as visible in any iteration of visualizing a given view of the CAD model 320 (and, in some implementations, not determined as visible for any iteration of visualizing any other view of the CAD model 320). In a subsequent (e.g., next) iteration of the CAD model view visualization process, the model visualization engine 110 may render the given view of the CAD model 320 by rendering any determined visible CAD parts as 3D geometry of the visible CAD parts via visualization data retrieved for the visible CAD parts and by rendering any non-visualized CAD parts as the bounding boxes of the non-visualized CAD parts via bounding box data for the non-visualized CAD parts.

As seen in FIG. 3, the (off-screen) rendering of the CAD model 320 may comprise rendered 3D geometry of visible CAD parts of the CAD model 320 as well as rendered bounding boxes of non-visualized CAD parts. To support image analysis of this background rendered view of the CAD model 320, the model visualization engine 110 may assign color values to the various CAD parts of the CAD model 320, including both visible CAD parts and non-visualized CAD parts, doing so such that non-visualized CAD parts can be uniquely identified. In some implementations, the model visualization engine 110 may assign all visible CAD parts for a given view of a CAD model the same color value, and as such any 3D geometry rendered off-screen may be colored by the same assigned color value (e.g., an RGB value of #000000 such that the 3D geometry of previously determined visible CAD parts are colored black in the combined off-screen rendering of the CAD model 320). In other implementations, the model visualization engine 110 may assign unique colors to each determined visible CAD part of a CAD model. Non-visualized CAD parts may be assigned unique color values, e.g., in a consistent manner as described herein, such that rendered bounding boxes are uniquely colored for each different non-visualized CAD part of a CAD model.

The model visualization engine 110 may render a given view of the CAD model as a combination of 3D geometry of visible CAD parts and bounding boxes of non-visualized CAD parts. Such a rendering may occur in as a background process, off-screen to a CAD user and thus not visible in the application window 322. In rendering such a view of the CAD model off-screen, the model visualization engine 110 may color each given CAD part (whether rendered as 3D geometry or a bounding box) as the single color assigned to the given CAD part. Thus, the model visualization engine 110 may color the 3D geometry of a visible CAD part entirely as a single color, without having to account for shading, lighting, shadows, or any other visual features of the rendered CAD part. In a consistent manner, the model visualization engine 110 may render each bounding box solely in a single color. Such single-color rendering of CAD parts may allow for proper image analysis and occlusion culling as described herein, but may also provide the technical benefit of reducing (at times significantly) the complexity of off-screen CAD model renderings. As such, the bounding box-based visualization technology described herein may support off-screen view renderings of CAD models as a combination of 3D geometry and bounding boxes with increased speed and reduced resource strain.

Next, the model visualization engine 110 may capture a 2D image of the combined 3D geometry-bounding box rendering, shown in FIG. 3 as the 2D image 330. In some examples, the model visualization engine 110 may set an image resolution of a captured 2D image 330 of a bounding box background rendering to be lesser than an image resolution of the view of the CAD model 320 with the visible CAD parts 240 visualized in the application window 322. Such image resolution control may be set by controlling the image resolution of the rendering of the combined 3D geometry-bounding box view of the CAD model or via the image capture process to capture the 2D image of the rendered view. By setting a lesser image resolution for rendering or 2D image capture of the off-screen rendered view, the model visualization engine 110 may improve the efficiency and speed of image analysis processes to determine visible CAD parts, as the rendering, image capture, and subsequent image analysis of captured 2D images for visible CAD part determination can require lesser computational resources and iteration latency when processing lesser amounts of visual data. The image resolution of captured 2D images may be a configurable parameter supported by the model visualization engine 110, and in some cases the model visualization engine 110 may set the image resolution of the captured 2D image 330 to be equal to the image resolution of the view of the CAD model 320 visualized in the application window 322 (e.g., to ensure a 1:1 pixel correlation and produce high-accuracy visible CAD part determinations and visualizations).

From a captured 2D image 330 of the view of a CAD model rendered via a combination of 3D geometry and bounding boxes, the model visualization engine 110 may determine visible CAD parts for a given iteration of a model visualization process. Visible CAD parts determined for a given iteration of a CAD model visualization process may also be referred to as additional visible CAD parts that are determined as distinct additions to the visible CAD parts determined in previous iterations for the visualizing of a particular view of a CAD model, determined as visible in any iteration for the visualizing of a different view of the CAD model (and thus with visualization data retrieved for visualizing the different view of the CAD model), or a combination thereof. In FIG. 3, the model visualization engine 110 captures and processes the 2D image 330 in which 3D geometry of previously determined visible CAD parts in a particular view of the CAD model 320 are colored as black (e.g., assigned a RGB value of #000000) and bounding boxes of non-visualized CAD parts are each colored with a uniquely assigned color value.

In the 2D image 330 of FIG. 3, the model visualization engine 110 may determine that pixel color values of the 2D image 330 include the assigned color values for four (4) different bounding boxes, labeled as pixel regions G, H, I, and J respectively. Accordingly, the model visualization engine 110 may determine additional visible CAD parts by analyzing the 2D image 330 of the view of the CAD model in a consistent manner as described herein. Each of the sections G-J may be colored by a different pixel color, and the pixel colors of sections G-J may correspond to four (4) different bounding boxes of four (4) different non-visualized CAD parts of the CAD model 320. The model visualization engine 110 may perform a lookup for the four (4) different pixel color values included in the 2D image 330 that correspond to assigned bounding box colors and identify the specific bounding boxes assigned these color values, which in turn can identify the four (4) corresponding non-visualized CAD parts. The model visualization engine 110 may determine these four (4) corresponding non-visualized CAD parts as the visible CAD parts 340 for the given iteration, which may be additional visible CAD parts to the visible CAD parts 240 previously determined for the given view of the CAD model in a different iteration of the model visualization process.

The model visualization engine 110 may then retrieve visualization data for the additional visible CAD parts 340 determined in this given iteration of the model visualization process and may visualize the additional visible CAD parts 340 in the application view 322 as part of visualizing the given view of the CAD model 320. The visible CAD parts 340 determined a current iteration of the model visualization process may be visualized in addition to the previously determined visible CAD parts 240. With each progressive iteration, the model visualization engine 110 may categorize additional visible CAD parts, and thus progressively load additional amounts of visualization data for the CAD model unto the client computing system 100. After a given iteration of the model visualization process, the model visualization engine 110 may visualize, in the application window 322, progressively more CAD parts for the given view of the CAD model 320 as long as additional visible CAD parts are determined via the off-screen bounding box rendering, capture, and image analysis of the bounding box-based visualization technology of the present disclosure.

The model visualization engine 110 may iteratively determine additional visible CAD parts for the visualization of given view of a CAD model until an ending criterion is reached. The model visualization engine 110 may set any number of suitable ending criterion in order to control the model visualization process for the given view of the CAD model, and various examples of ending criteria are presented herein. As one example, the ending criterion may be satisfied when the 2D image captured for the rendering of the CAD model via a combination of 3D geometry of visible CAD parts and bounding boxes for non-visualized CAD parts does not include any pixel color values that are assigned to a bounding box. Satisfaction of this ending criterion may indicate that no bounding boxes of non-visualized CAD parts of the CAD model are visible in the rendered view of the CAD model as the 2D image may include only pixel color value(s) of 3D geometry of visible CAD parts. In such cases, the model visualization engine 110 may determine zero (0) additional visible CAD parts for the given iteration and need not continue to iteratively determine visible CAD parts for the given view of the CAD model.

As other examples, the ending criterion may be satisfied based on any number of thresholds to limit how long the model visualization engine 110 performs iterative determinations of additional visible CAD elements. Such ending criterion may be satisfied when a threshold number of iterations are performed by the model visualization engine 110 to determine additional visible CAD parts (e.g., after ten (10) iterations, which can represent a maximum number of iterations to perform), after a threshold amount of time has elapsed in performing the iterations (e.g., a timeout length of 10 seconds), or any other suitable threshold to limit iteration performance. As yet another example, the ending criterion may be satisfied when a user or a CAD application changes the view of the CAD model to a different view. In such cases, the model visualization engine 110 may no longer need to determine visible CAD parts for the given view and instead restart the new model visualization process, this time for the new view of the CAD model.

As yet a further example, the ending criterion for iterations of a particular model visualization process may be satisfied when a render (or re-render) command is issued by the CAD application. In such cases, changes (e.g., user selections, model vanish functions, or other adjustments to the display of the CAD model of the current view) may cause the CAD application to re-render the CAD model through issuance of a render command for the CAD model (which may be the same view). In such cases, the model visualization engine 110 may cease iterations of the current model visualization process and restart the model visualization process to account for the changes. Accordingly, the model visualization engine 110 may visualize the same view of the CAD model, but restart the model visualization process to account for the applied vanish function or any other applicable CAD model change that causes issuance of the render command.

The model visualization engine 110 may apply any combination of various examples of ending criterion described herein in performing iterations of a model visualization process (e.g., to iteratively determine additional visible CAD elements for a given view of a CAD model).

In any of the ways described herein, the model visualization engine 110 may support bounding box-based determinations of visible CAD parts for views of CAD models. Through the use of simplified shapes to represent CAD parts instead of full-detail 3D geometry, the bounding box-based visualization technology of the present disclosure may reduce initial transmission times to obtain CAD model data from cloud servers through transmission of bounding box data instead of full detail 3D geometry. Additionally, the features of the present disclosure can reduce computational requirements and rendering latencies for CAD model views to support determinations of visible CAD parts, as bounding boxes can be rendered with significantly increased speed as compared to complex full-detail 3D geometries. Through the use of 2D image analyses, pixel color comparisons may reduce the time and complexity of occlusion culling for CAD parts as compared to conventional complex geometric operations needed to compare 3D geometries of the many CAD parts that comprise a CAD model. As such, the bounding box-based visualization technology of the present disclosure may provide tangible technical benefits in the visualization of views of CAD models.

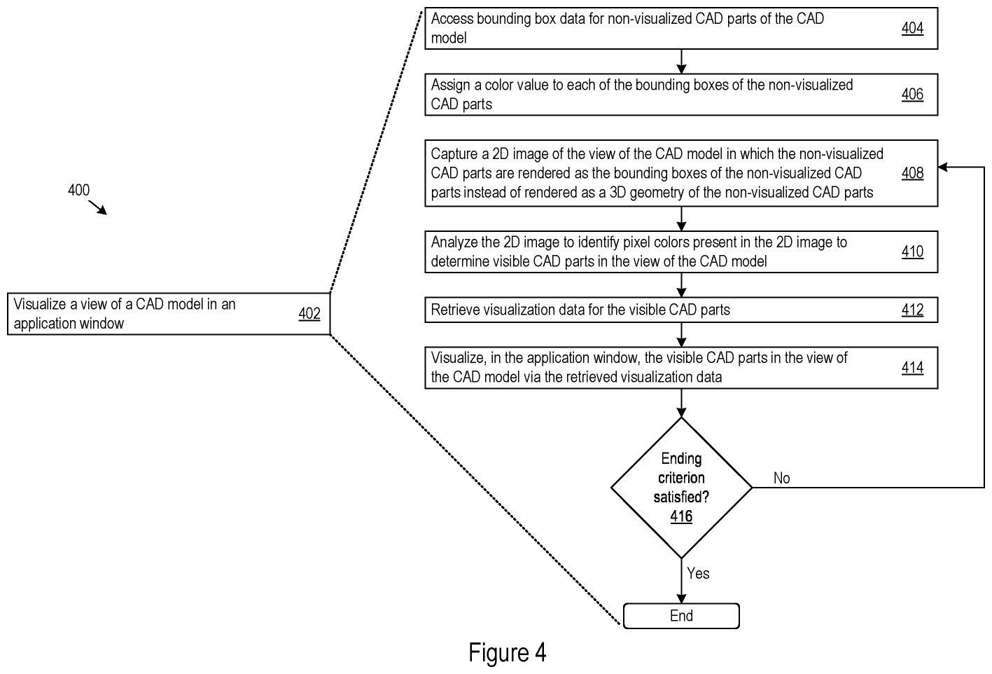

FIG. 4 shows an example of logic 400 that a system may implement to support bounding box-based visualization of CAD models via pixel color analyses. For example, the client computing system 100 may implement the logic 400 as hardware, executable instructions stored on a machine-readable medium, or as a combination of both. The client computing system 100 may implement the logic 400 via the model visualization engine 110, through which the client computing system 100 may perform or execute the logic 400 as a method to support bounding box-based visualization of CAD models. The following description of the logic 400 is provided using the model visualization engine 110 as an example. However, various other implementation options by systems are possible.

In implementing the logic 400, the model visualization engine 110 may visualize a view of a CAD model in an application window (402), including by accessing bounding box data for non-visualized CAD parts of the CAD model (404). As noted herein, the non-visualized CAD parts include CAD parts of the CAD model for which visualization data has not been retrieved by a client computing system and the bounding box data for the non-visualized CAD parts may represent a respective bounding box for the non-visualized CAD parts of the CAD model. In visualizing the view of the CAD model in the application window, the model visualization engine 110 may also assign a color value to each of the bounding boxes of the non-visualized CAD parts (406), capture a 2D image of the view of the CAD model in which the non-visualized CAD parts are rendered as the bounding boxes of the non-visualized CAD parts instead of rendered as a 3D geometry of the non-visualized CAD parts (408), and analyze the 2D image to identify pixel colors present in the 2D image to determine visible CAD parts in the view of the CAD model (410), doing so in any of the ways described herein. In implementing the logic 400, the model visualization engine 110 may visualize the view of the CAD model in the application window further by retrieving visualization data for the visible CAD parts (412) and visualizing, in the application window, the visible CAD parts in the view of the CAD model via the retrieved visualization data (414).

In any of the ways described herein, the model visualization engine 110 may iteratively determine additional visible CAD parts in visualizing the view of the CAD model. In the logic 400 of FIG. 4, the model visualization engine 110 may iteratively determine additional visible CAD parts to visualize the view of the CAD model until an ending criterion is reached. As such, in implementing the logic 400, the model visualization engine 110 may determine if an ending criterion is reached (416). Responsive to a determination that the ending criterion is not reached, the model visualization engine 110 may continue to capture 2D images of rendered bounding boxes of non-visualized CAD parts (which may include rendered 3D geometry of previously determined visible CAD parts), analyze the 2D images to identify pixel colors present to determine visible CAD parts for the current iteration, retrieve visualization data for the visible CAD parts determined for the current iteration, and visualize the visible CAD parts additionally determined in current iteration. Put another way, the model visualization engine 110 may iteratively perform the capturing, the analyzing, the retrieving, and the visualizing until an ending criterion is reached (e.g., satisfied).

In some implementations, in each iteration, the model visualization engine 110 may assign colors for visible CAD parts, non-visualized CAD parts, or a combination of both. In a given iteration, the model visualization engine 110 may assign a pixel color to each of the bounding boxes of the non-visualized CAD parts of the CAD model and assigning a pixel color to each visible CAD part of the CAD model (which in some implementations is the same color for each visible CAD part). Capture of the 2D image in a given iteration may comprise capturing a 2D image of the view of the CAD model rendered using the bounding boxes for the non-visualized CAD parts instead of rendered using the visualization data of the non-visualized CAD parts and also rendered using the visualization data (e.g., 3D geometry) of the visible CAD parts of the CAD model.

Responsive to a determination that the ending criterion is reached, the model visualization engine 110 may cease determination and visualization of additional visible CAD parts for the view of the CAD model visualized in the application window (though the model visualization engine 110 may continue to visualize the view of the CAD model in the application window until a different view of the CAD model is to be visualized or a render command is issued to re-render the view of the CAD model in an application window).

The logic 400 shown in FIG. 4 provides but one example by which a client computing system 100 may support bounding box-based visualization of CAD models via pixel color analyses. Additional or alternative steps in the logic 400 are contemplated herein, including according to any features described for the model visualization engine 110.

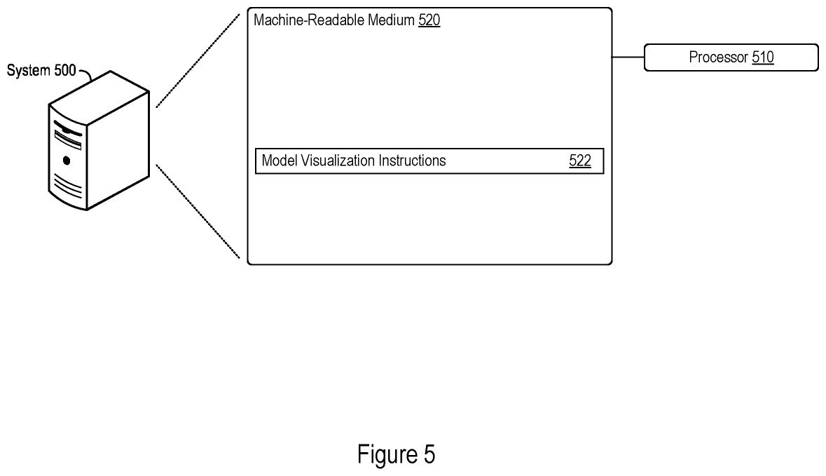

FIG. 5 shows an example of a system 500 that supports bounding box-based visualization of CAD models via pixel color analyses. The system 500 may include a processor 510, which may take the form of a single or multiple processors. The processor(s) 510 may include a central processing unit (CPU), microprocessor, or any hardware device suitable for executing instructions stored on a machine-readable medium. The system 500 may include a machine-readable medium 520. The machine-readable medium 520 may take the form of any non-transitory electronic, magnetic, optical, or other physical storage device that stores executable instructions, such as the model visualization instructions 522 shown in FIG. 5. As such, the machine-readable medium 520 may be, for example, Random Access Memory (RAM) such as a dynamic RAM (DRAM), flash memory, spin-transfer torque memory, an Electrically-Erasable Programmable Read-Only Memory (EEPROM), a storage drive, an optical disk, and the like.

The system 500 may execute instructions stored on the machine-readable medium 520 through the processor 510. Executing the instructions (e.g., the model visualization instructions 522) may cause the system 500 to perform any of the bounding box-based visualization features described herein, including according to any of the features with respect to the model visualization engine 110.

For example, execution of the model visualization instructions 522 by the processor 510 may cause the system 500 to visualize a view of a CAD model in an application window, including by accessing bounding box data for non-visualized CAD parts of the CAD model, assigning a color value to each of the bounding boxes of the non-visualized CAD parts, capturing a 2D image of the view of the CAD model rendered using the bounding boxes for the non-visualized CAD parts instead of rendered using visualization data of the non-visualized CAD parts, analyzing the 2D image to identify pixel colors present in the 2D image to determine visible CAD parts in the view of the CAD model, wherein the visible CAD parts correspond to bounding boxes of non-visualized CAD parts determined as visible based on the identified pixel colors. Execution of the model visualization instructions 522 by the processor 510 may also cause the system 500 to visualize the view of the CAD model in the application window by retrieving visualization data for the visible CAD parts and visualizing, in the application window, the visible CAD parts in the view of the CAD model via the retrieved visualization data.

Any additional or alternative features of the present disclosure may be implemented via the model visualization instructions 522.

The systems, methods, devices, and logic described above, including the client computing system 100, model visualization engine 110, and server computing system 202, may be implemented in many different ways in many different combinations of hardware, logic, circuitry, and executable instructions stored on a machine-readable medium. For example, the client computing system 100, model visualization engine 110, server computing system 202, or combinations thereof, may include circuitry in a controller, a microprocessor, or an application specific integrated circuit (ASIC), or may be implemented with discrete logic or components, or a combination of other types of analog or digital circuitry, combined on a single integrated circuit or distributed among multiple integrated circuits. A product, such as a computer program product, may include a storage medium and machine-readable instructions stored on the medium, which when executed in an endpoint, computer system, or other device, cause the device to perform operations according to any of the description above, including according to any features of the model visualization engine 110.

The processing capability of the systems, devices, and engines described herein, including the model visualization engine 110, may be distributed among multiple system components, such as among multiple processors and memories, optionally including multiple distributed processing systems or cloud/network elements. Parameters, databases, and other data structures may be separately stored and managed, may be incorporated into a single memory or database, may be logically and physically organized in many different ways, and may be implemented in many ways, including data structures such as linked lists, hash tables, or implicit storage mechanisms. Programs may be parts (e.g., subroutines) of a single program, separate programs, distributed across several memories and processors, or implemented in many different ways, such as in a library (e.g., a shared library).

While various examples have been described above, many more implementations are possible.

1. A method comprising:
visualizing, by a client computing system, a view of a computer-aided design (CAD) model in an application window, wherein the CAD model is comprised of CAD parts and wherein the CAD parts are discrete components of the CAD model, including by:
accessing bounding box data for non-visualized CAD parts of the CAD model, wherein the non-visualized CAD parts comprise CAD parts of the CAD model for which visualization data has not been retrieved by the client computing system and wherein the bounding box data for the non-visualized CAD parts represent a respective bounding box for the non-visualized CAD parts of the CAD model;
assigning a color value to each of the bounding boxes of the non-visualized CAD parts;
capturing a 2D image of the view of the CAD model in which the non-visualized CAD parts are rendered as the bounding boxes of the non-visualized CAD parts instead of rendered as a 3D geometry of the non-visualized CAD parts;
analyzing the 2D image to identify pixel colors present in the 2D image to determine visible CAD parts in the view of the CAD model, wherein the visible CAD parts correspond to bounding boxes of non-visualized CAD parts determined as visible based on the identified pixel colors;
retrieving visualization data for the visible CAD parts; and
visualizing, in the application window, the visible CAD parts in the view of the CAD model via the retrieved visualization data.

2. The method of claim 1, comprising accessing the bounding box data for the non-visualized CAD parts and retrieving the visualization data for the visible CAD parts from a cloud server remote to the client computing system.

3. The method of claim 1, comprising iteratively performing the capturing, the analyzing, the retrieving, and the visualizing until an ending criterion is reached.

4. The method of claim 3, wherein, in a given iteration, assigning comprises:
assigning a pixel color to each of the bounding boxes of the non-visualized CAD parts of the CAD model; and
assigning a pixel color to each visible CAD part of the CAD model.

5. The method of claim 3, wherein, in a given iteration, capturing comprises capturing a 2D image of the view of the CAD model rendered using the bounding boxes for the non-visualized CAD parts instead of rendered using the visualization data of the non-visualized CAD parts and also rendered using the visualization data of the visible CAD parts of the CAD model.

6. The method of claim 3, wherein the ending criterion is reached when the 2D image does not include any pixel color assigned to the bounding boxes of the non-visualized CAD parts of the CAD model.

7. The method of claim 1, further comprising setting an image resolution of the 2D image to be lesser than an image resolution of the view of the CAD model with the visible CAD parts visualized in the application window.

8. A system comprising:
a model visualization engine configured to visualize a view of a computer-aided design (CAD) model in an application window, wherein the CAD model is comprised of CAD parts and wherein the CAD parts are discrete components of the CAD model, including by:
accessing bounding box data for non-visualized CAD parts of the CAD model, wherein the non-visualized CAD parts comprise CAD parts of the CAD model for which visualization data has not been retrieved by the client computing system and wherein the bounding box data for the non-visualized CAD parts represent a respective bounding box for the non-visualized CAD parts of the CAD model;
assigning a color value to each of the bounding boxes of the non-visualized CAD parts;
capturing a 2D image of the view of the CAD model rendered using the bounding boxes for the non-visualized CAD parts instead of rendered using visualization data of the non-visualized CAD parts;
analyzing the 2D image to identify pixel colors present in the 2D image to determine visible CAD parts in the view of the CAD model, wherein the visible CAD parts correspond to bounding boxes of non-visualized CAD parts determined as visible based on the identified pixel colors;
retrieving visualization data for the visible CAD parts; and
visualizing, in the application window, the visible CAD parts in the view of the CAD model via the retrieved visualization data.

9. The system of claim 8, wherein the model visualization engine is configured to render the 2D image of the view of the CAD model as a background image that is not visualized in the application window.

10. The system of claim 8, comprising iteratively performing the capturing, the analyzing, the retrieving, and the visualizing until an ending criterion is reached.

11. The system of claim 10, wherein, in a given iteration, the model visualization engine is configured to:
assign a pixel color to each of the bounding boxes of the non-visualized CAD parts of the CAD model; and
assign a pixel color to each visible CAD part of the CAD model.

12. The system of claim 10, wherein, in a given iteration, the model visualization engine is configured to render the 2D image of the view of the CAD model using the bounding boxes for the non-visualized CAD parts and using the visualization data of the visible CAD parts of the CAD model.

13. The system of claim 10, wherein the ending criterion is reached when the 2D image does not include any pixel color assigned to the bounding boxes of the non-visualized CAD parts of the CAD model.

14. The system of claim 10, wherein the model visualization engine is further configured to set an image resolution of the 2D image to be lesser than an image resolution of the view of the CAD model with the visible CAD parts visualized in the application window.

15. A non-transitory machine-readable medium comprising instructions that, when executed by a processor, cause a client computing system to visualize a view of a computer-aided design (CAD) model in an application window, wherein the CAD model is comprised of CAD parts and wherein the CAD parts are discrete components of the CAD model, including by:
accessing bounding box data for non-visualized CAD parts of the CAD model, wherein the non-visualized CAD parts comprise CAD parts of the CAD model for which visualization data has not been retrieved by the client computing system and wherein the bounding box data for the non-visualized CAD parts represent a respective bounding box for the non-visualized CAD parts of the CAD model;
assigning a color value to each of the bounding boxes of the non-visualized CAD parts;
capturing a 2D image of the view of the CAD model rendered using the bounding boxes for the non-visualized CAD parts instead of rendered using visualization data of the non-visualized CAD parts;
analyzing the 2D image to identify pixel colors present in the 2D image to determine visible CAD parts in the view of the CAD model, wherein the visible CAD parts correspond to bounding boxes of non-visualized CAD parts determined as visible based on the identified pixel colors;
retrieving visualization data for the visible CAD parts; and
visualizing, in the application window, the visible CAD parts in the view of the CAD model via the retrieved visualization data.

16. The non-transitory machine-readable medium of claim 15, wherein the instructions cause the client computing system to render the 2D image of the view of the CAD model as a background image that is not visualized in the application window.

17. The non-transitory machine-readable medium of claim 15, comprising iteratively performing the capturing, the analyzing, the retrieving, and the visualizing until an ending criterion is reached.

18. The non-transitory machine-readable medium of claim 17, wherein, in a given iteration, the instructions cause the client computing system to:
assign a pixel color to each of the bounding boxes of the non-visualized CAD parts of the CAD model; and
assign a pixel color to each visible CAD part of the CAD model.

19. The non-transitory machine-readable medium of claim 17, wherein, in a given iteration, the instructions cause the client computing system to render the 2D image of the view of the CAD model using the bounding boxes for the non-visualized CAD parts and using the visualization data of the visible CAD parts of the CAD model.

20. The non-transitory machine-readable medium of claim 17, wherein the ending criterion is reached when the 2D image does not include any pixel color assigned to the bounding boxes of the non-visualized CAD parts of the CAD model.
